(19) United States
(12) Patent Application Publication
(10) Pub. No.: US 2010/0157554 A1
(43) Pub. Date: Jun. 24, 2010

(54) FIXING MECHANISM CAPABLE OF REDUCING ELECTROMAGNETIC RADIATION INTERFERENCE

(76) Inventor: Chih-Kang Ho, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/509,497

(22) Filed: Jul. 27, 2009

(30) Foreign Application Priority Data
Dec. 24, 2008 (TW) 097223152

(51) Int. Cl. H05K 5/00; F16B 43/00; F16B 33/00

(52) U.S. Cl. 361/753; 411/531; 411/378

(57) ABSTRACT

A fixing mechanism capable of reducing electromagnetic radiation interference includes a fixing component passing through a first hole on a circuit board and a second hole on a casing so as to fix the circuit board on the casing, and a conductive film covering the fixing component for contacting the circuit board and the casing so as to ground the circuit board via the casing.

### BACKGROUND OF THE INVENTION

1. Field of the Invention

The present invention relates to a fixing mechanism, and more particularly, to a fixing mechanism capable of reducing electromagnetic radiation interference on an electronic device.

2. Description of the Prior Art

An ordinary electronic device is composed of several modules, such as a central processing unit, a memory, a circuit board, a hard disc, a power supply, and so on. The modules installed inside a casing communicate to each other by sorts of conducting wires, and electronic signals communicated by the conducting wires are transmitted within a high frequency band. For example, electromagnetic interference generated by data strobe impulse of a double data rate (DDR) memory disposed on a circuit board is an ordinary but troublesome problem. Electromagnetic radiation is generated by the double data rate memory while processing with high frequency signals. In a test of the electromagnetic interference, intense interference of the electromagnetic radiation is generated within the high frequency band, such as 1 GHz. In a period of using upgrading programming software, operating speed and capacity of the double data rate memory are demanded progressively, and damage on users or surroundings affected by the electromagnetic radiation becomes a serious problem. Nowadays, methods capable of reducing the electromagnetic interference are nothing more than adjusting capacitance around the memory and changing layout design. However data transmission techniques are greatly advanced, and the electromagnetic interference gets out of control and becomes an unsound problem. Therefore, many countries in the world formulate their own testing standard of the electromagnetic interference, and there are more and more researches for reducing the electromagnetic radiation in the world.

Please refer to FIG. 1. FIG. is a diagram of an electronic device 10 without installing a structure capable of reducing electromagnetic interference in the prior art. The electronic device 10 includes a circuit board 12 whereon a first hole 121 is disposed, a casing 14 whereon a second hole 141 is disposed, and a fixing mechanism 16. A fixing method of the electronic device 10 includes choosing the fixing mechanism 16 conforming to dimensions of the first hole 121 of the circuit board 12 and the second hole 141 of the casing 14, passing the fixing mechanism 16 through the first hole 121 of the circuit board 12 and the second hole 141 of the casing 14 in turn, and locking up the fixing mechanism 16 for connecting and fixing the circuit board 12 and the casing 14 finally.

Please refer to FIG. 2. FIG. 2 is a chart illustrating electromagnetic radiation generated by the electronic device 10 without installing the structure capable of reducing the electromagnetic interference in the prior art. A horizontal axis in FIG. 2 illustrates a frequency variation value of the high frequency signals transmitted by the circuit board 12 while processing, and unit of the horizontal axis is mega hertz. An impulse signal is generated while the high frequency signals are transmitted, and the electromagnetic interference is caused by a tip of the impulse signal. A vertical axis in FIG. 2 illustrates a measuring datum of the electromagnetic interference. As shown in FIG. 2, the electromagnetic interference at maximum value of the high frequency signal, such as 924 MHz, is about −2.5 dB.

Conventional methods for reducing the electromagnetic interference include installing a metal casing so as to prevent leaking the electromagnetic radiation, such as a galvanized steel plate, forming a dot inside the casing for preventing the electromagnetic interference, and installing a preferred slot baffle so as to isolate the electromagnetic radiation. However, internal circuits of the electronic device are more complicated and powerful, and the electromagnetic interference is also more serious. There are more doubts of designing the casing for isolating the electromagnetic interference. For example, a gap between the casing and the slot baffle may be deformed by external forces so as to leak the electromagnetic radiation. Thus, there is a need to design an electronic device capable of reducing the electromagnetic radiation effectively.

### SUMMARY OF THE INVENTION

According to the claimed invention, a fixing mechanism comprising a fixing component passing through a first hole on a circuit board and a second hole on a casing so as to fix the circuit board on the casing, and a conductive film covering the fixing component for contacting the circuit board and the casing so as to ground the circuit board via the casing.

According to the claimed invention, an electronic device comprising a circuit board whereon a first hole is formed, a casing whereon a second hole is formed, and a fixing mechanism comprising a fixing component passing through the first hole on the circuit board and the second hole on the casing so as to fix the circuit board on the casing, and a conductive film covering the fixing component for contacting the circuit board and the casing so as to ground the circuit board via the casing.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an electronic device without installing a structure capable of reducing electromagnetic interference in the prior art.

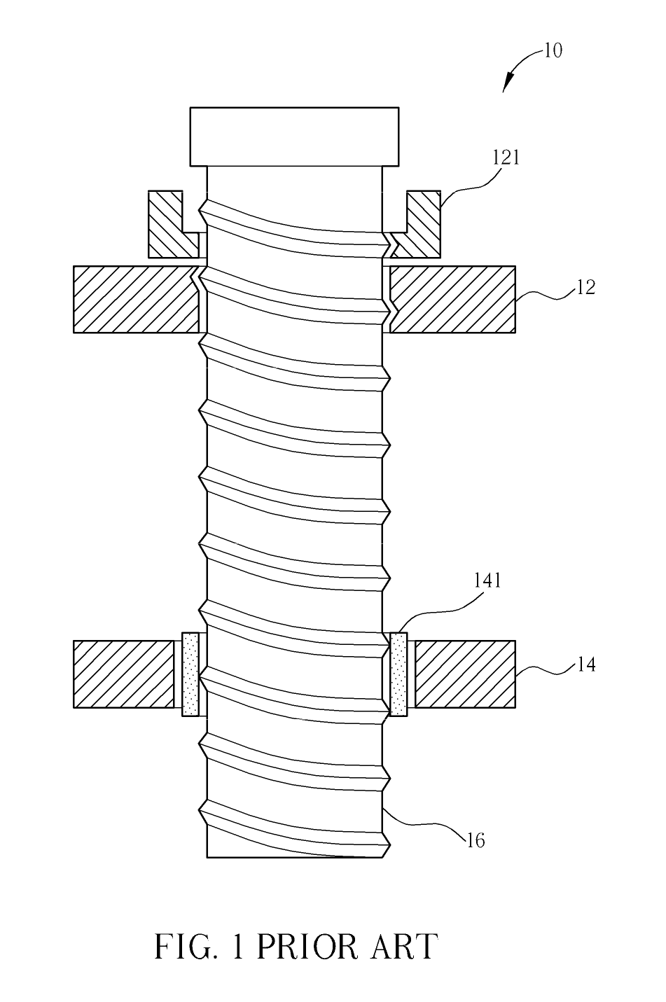

FIG. 2 is a chart illustrating electromagnetic radiation generated by the electronic device without installing the structure capable of reducing the electromagnetic interference in the prior art.

FIG. 3 is a diagram of a fixing mechanism capable of reducing the electromagnetic interference according to a first embodiment of the present invention.

FIG. 4 is a chart illustrating electromagnetic radiation generated by the fixing mechanism capable of reducing the electromagnetic interference according to the first embodiment of the present invention.

FIG. 5 is a diagram of the fixing mechanism capable of reducing the electromagnetic interference according to a second embodiment of the present invention.

### DETAILED DESCRIPTION

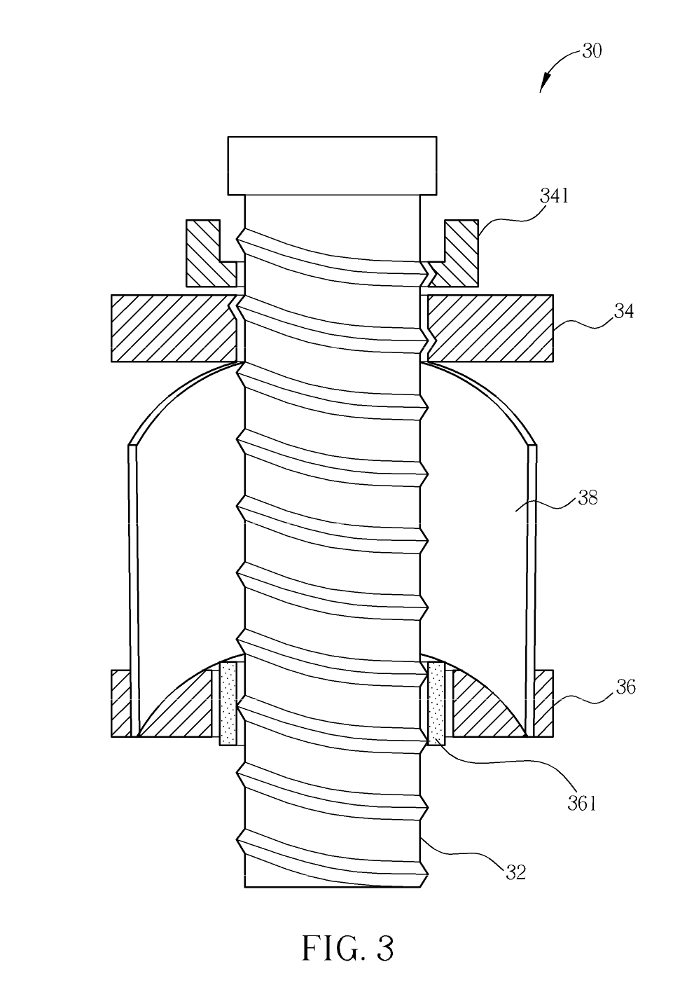

Please refer to FIG. 3. FIG. 3 is a diagram of a fixing mechanism 30 capable of reducing electromagnetic interference according to a first embodiment of the present invention. The fixing mechanism 30 includes a fixing component 32 passing through a first hole 341 of a circuit board 34 and a second hole 361 of a casing 36 so as to fix the circuit board 34 on the casing 36, and a conductive film 38 covering the fixing component 32 for contacting the circuit board 34 and the casing 35 so as to ground the circuit board 34 via the casing. The fixing component 32 can be a rivet and a bolt, etc. The conductive film 38 can be made of aluminum or copper material and can be glued on a surface of the fixing component 32. In this embodiment, the fixing component 32 is used for connecting the circuit board 34 and the casing 35, and can be covered by a 4 cm×4 cm conductive film 38 so as to reduce electromagnetic interference. Assembly of the fixing component 30 includes following steps:

STEP1: Choose the circuit board 34.

STEP2: Choose the casing 36.

STEP3: Choose the fixing component 32 conforming to dimensions of the first hole 341 of the circuit board 34 and the second hole 361 of the casing 36, and pass the fixing component 32 through the first hole 341 of the circuit board 34 and the second hole 361 of the casing 36.

STEP4: Choose the conductive film 38 for covering the surface of the fixing component 32 and contacting the circuit board 34 and the casing 36 at the same time.

STEP5: Lock up the fixing component 32 for connecting and fixing the circuit board 34 and the casing 36.

STEP6: End.

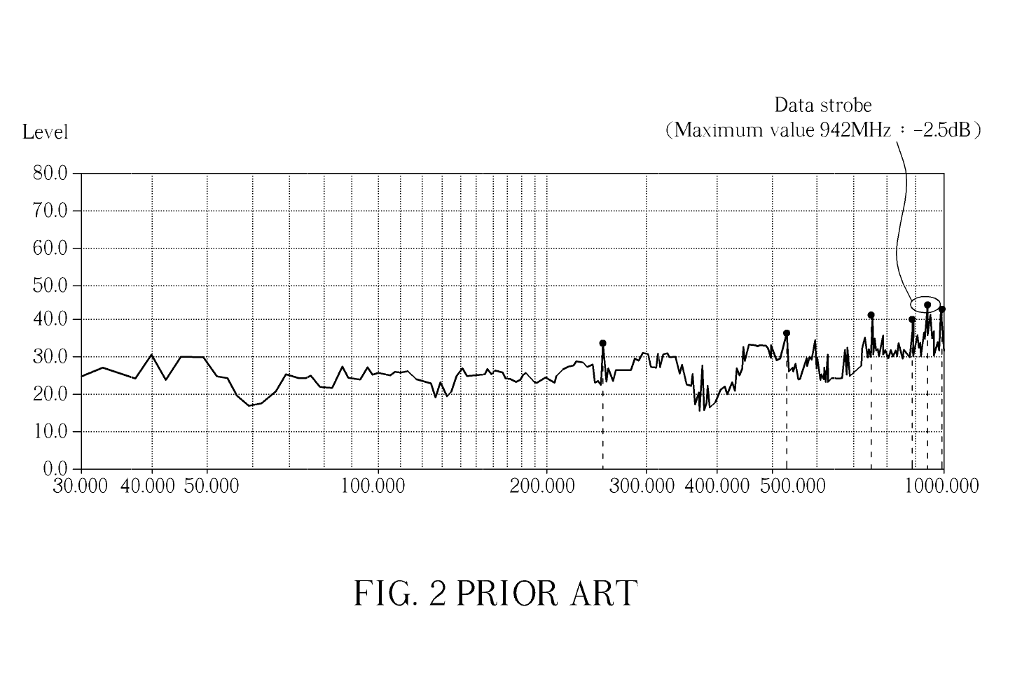

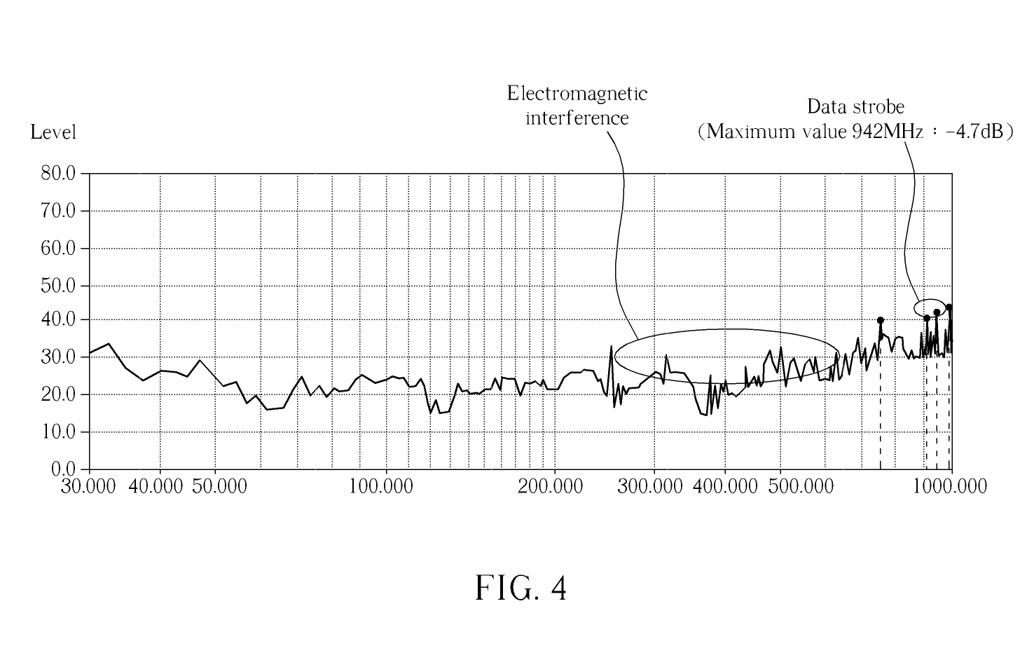

Please refer to FIG. 4. FIG. 4 is a chart illustrating electromagnetic radiation generated by the fixing mechanism 30 capable of reducing the electromagnetic interference according to the first embodiment of the present invention. In this embodiment, enormous electromagnetic radiation is generated by high frequency signals while the circuit board 34 operates for high speed programming. Due to the conductive film 38 covering on the fixing component 32, grounding efficiency of the circuit board 34 can be increased so as to reduce leakage of the electromagnetic radiation dissipated by the circuit board 34. Definition of the horizontal axis and the vertical axis in FIG. 4 are the same as the ones shown in FIG. 2, and detailed descriptions are omitted herein for simplicity. As shown in FIG. 4, while the high frequency signal is at maximum value of the frequency band, such as 924 MHz, value of the electromagnetic interference is about −4.7 dB. In contrast to the value of the electromagnetic interference shown in FIG. 2, measured datum decreases as 2.2 dB and an average range of the electromagnetic interference between the high frequency band, such as the range between 250 MHz and 1 GHz, improves obviously as shown in the sections marked by an ellipse in FIG. 4. The average of crest values shown in FIG. 4 is smaller than the crest values within same high frequency band shown in FIG. 2.

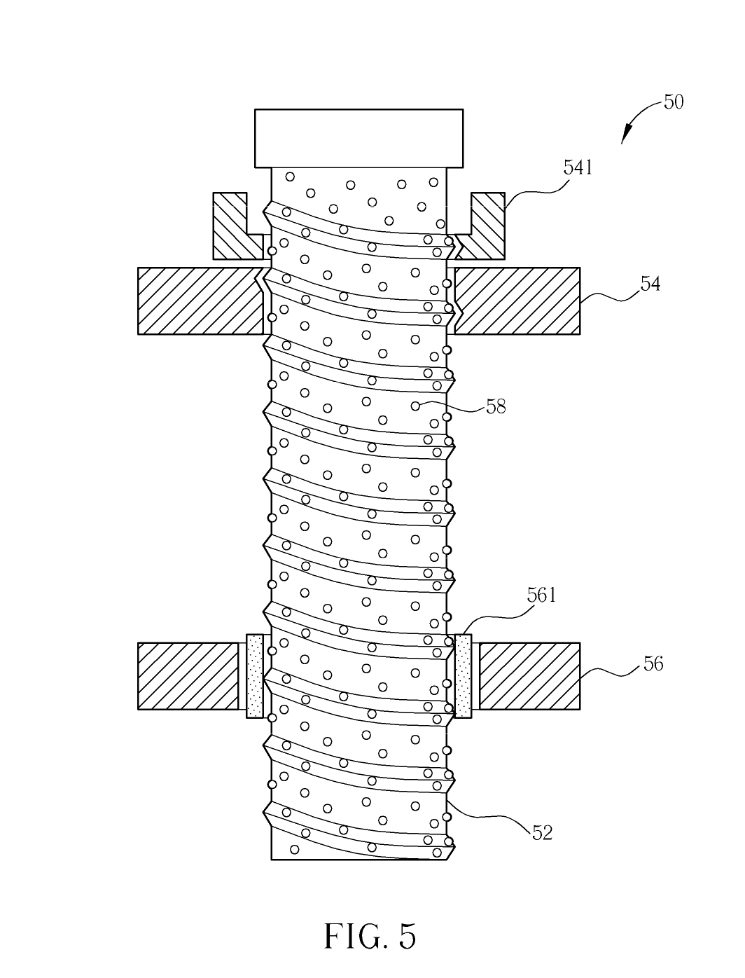

Please refer to FIG. 5. FIG. 5 is a diagram of a fixing mechanism 50 capable of reducing the electromagnetic interference according to a second embodiment of the present invention. The fixing mechanism 50 includes a fixing component 52 passing through a first hole 541 of a circuit board 54 and a second hole 561 of a casing 56 so as to fix the circuit board 54 on the casing 56, and a conductive film 58 covering the fixing component 52 for contacting the circuit board 54 and the casing 56 so as to ground the circuit board 54 via the casing 56. Difference between the second embodiment and the first embodiment is that the conductive film 58 is coated on a surface of the fixing component 52 in the second embodiment so as to increase contacting areas and improve grounding efficiency for reducing the electromagnetic interference. Assembly of the fixing mechanism 50 includes following steps:

STEP1: Choose the circuit board 54.

STEP2: Choose the casing 56.

STEP3: Choose the fixing component 52 conforming to dimensions of the first hole 541 of the circuit board 54 and the second hole 561 of the casing 56.

STEP4: Coat the conductive film 58 on the surface of the fixing component 52 by sputtering process or vapor deposition method.

STEP5: Pass the fixing component 52 through the first hole 541 of the circuit board 54 and the second hole 561 of the casing 56 in turn.

STEP6: Screw the fixing component 52 for connecting and fixing the circuit board 54 and the casing 56.

STEP7: End.

In addition, the fixing component 52 can not be limited to a screw and can be any sort of locking structure or wedging structure. The fixing component 52 can be coated by the conductive film 58 as using the sputtering process or the vapor deposition method so as to improve the grounding efficiency and reduce the electromagnetic interference effectively. Except the fixing component having a special purpose, the grounding efficiency can be improved for reducing the electromagnetic interference not only by increasing the contacting area between the circuit board and the fixing component, but also by designing the conductive film having the special purpose.

In summary, the electronic device according to the present invention can be proved for reducing the electromagnetic interference effectively, and includes following advantages:
1. The fixing mechanism capable of reducing the electromagnetic interference improves damage of the electromagnetic interference caused by the data strobe impulse of a double data rate memory.
2. The present invention not only can improve the grounding efficiency, but also can enhance electrostatic protection.
3. The present invention also can reduce noises of a grounding portion for improving the electromagnetic interference within other frequency band.
4. The present invention is easy to apply and has low cost. Effect of reducing the electromagnetic interference is obvious and safe.
5. The present invention can be used extensively on all sorts of enclosed electronic apparatus, such as computers, servers, and video game machines, and also can be used on all sorts of computer apparatus having main board devices which need to improve electrostatic protections.

In contrast to the prior art, the electronic device capable of reducing the electromagnetic interference according to the present invention utilizes the conductive film to cover the fixing component so as to ground the circuit board via the casing. Therefore, the grounding efficiency can be improved for reducing the electromagnetic radiation. The present invention can restrain the electromagnetic radiation generated by the circuit board. The present invention can improve the problems in the prior art for isolating the electromagnetic radiation inside the casing so as to avoid leaking out, such as a convex surface inside the casing and a slot baffle on the casing, or can improve the problems in the prior art for adjusting capacitance and layout design so as to restrain the electromagnetic radiation. The present invention improves neglect of the ground efficiency in the prior art so as to reduce damage generated from the electromagnetic radiation effectively.

Those skilled in the art will readily observe that numerous modifications and alterations of the device and method may be made while retaining the teachings of the invention.

What is claimed is:

1. A fixing mechanism comprising:
a fixing component passing through a first hole on a circuit board and a second hole on a casing so as to fix the circuit board on the casing; and
a conductive film covering the fixing component for contacting the circuit board and the casing so as to ground the circuit board via the casing.

2. The fixing mechanism of claim 1, wherein the conductive film is made of aluminum or copper material.

3. The fixing mechanism of claim 1, wherein the conductive film is glued on a surface of the fixing component.

4. The fixing mechanism of the claim 1, wherein the conductive film is coated on a surface of the fixing component.

5. The fixing mechanism of the claim 4, wherein the conductive film is formed on the surface of the fixing component by sputtering process or vapor deposition method.

6. The fixing mechanism of the claim 1, wherein the fixing component is a rivet.

7. The fixing mechanism of the claim 1, wherein the fixing component is a bolt.

8. The fixing mechanism of claim 1, wherein the fixing component is used for screwing the circuit board on the casing.

9. The fixing mechanism of the claim 8, wherein the fixing component is a screw.

10. The fixing mechanism of claim 1, wherein the circuit board is a main board.

11. An electronic device comprising:
a circuit board whereon a first hole is formed;
a casing whereon a second hole is formed; and
a fixing mechanism comprising:
a fixing component passing through the first hole on the circuit board and the second hole on the casing so as to fix the circuit board on the casing; and
a conductive film covering the fixing component for contacting the circuit board and the casing so as to ground the circuit board via the casing.

12. The electronic device of claim 11, wherein the conductive film is made of aluminum or copper material.

13. The electronic device of claim 11, wherein the conductive film is glued on a surface of the fixing component.

14. The electronic device of claim 11, wherein the conductive film is coated on a surface of the fixing component.

15. The electronic device of claim 14, wherein the conductive film is formed on the surface of the fixing component by sputtering process or vapor deposition method.

16. The electronic device of claim 11, wherein the fixing component is a rivet.

17. The electronic device of claim 11, wherein the fixing component is a bolt.

18. The electronic device of claim 11, wherein the fixing component is used for screwing the circuit board on the casing.

19. The electronic device of claim 18, wherein the fixing component is a screw.

20. The electronic device of claim 11, wherein the circuit board is a main board.
